(19) United States
(12) Patent Application Publication
(10) Pub. No.: US 2014/0117356 A1
(43) Pub. Date: May 1, 2014

(54) SEMICONDUCTOR STRUCTURE FOR IMPROVED OXIDE FILL IN

(71) Applicant: MACRONIX INTERNATIONAL CO., LTD., Hsinchu (TW)

(72) Inventors: Jeng Hwa Liao, Hsinchu City (TW); Jung Yu Shieh, Hsinchu City (TW); Ling Wuu Yang, Hsinchu City (TW)

(73) Assignee: MACRONIX INTERNATIONAL CO., LTD., Hsinchu (TW)

(21) Appl. No.: 13/663,676

(22) Filed: Oct. 30, 2012

(51) Int. Cl. H01L 29/04; H01L 21/20

(52) U.S. Cl. 257/49; 438/488; 257/E21.09; 257/E29.003

(57) ABSTRACT

A semiconductor device includes a substrate, a semiconductor layer, and a material layer. The semiconductor layer is formed over the substrate. The material layer is formed over the semiconductor layer. The semiconductor layer and the material layer have a tapered profile in a vertical direction extending from the substrate.

### BACKGROUND

The present application relates generally to semiconductor devices and includes methods and structures for improving fill in, such as oxide fill in, between structures.

An important capability for manufacturing reliable integrated circuits is to reliably fill in spaces between structures. For example, it may be necessary to prevent contact between two structures such that a short does not form. The space between the structures may be filled in with an oxide. However, if a void is formed in the oxide between the structures, later processing steps such as cleaning and depositing a conducting material may undesirably result in conductive material deposited between the structures allowing a short to be formed between the structures.

### BRIEF SUMMARY

According to an aspect, a semiconductor device includes a substrate, a semiconductor layer, and a material layer. The semiconductor layer is formed over the substrate. The material layer is formed over the semiconductor layer. The semiconductor layer and the material layer have a tapered profile in a vertical direction extending from the substrate. A face of the semiconductor layer and a face of the material layer are coplanar.

According to another aspect, a method of forming a semiconductor device includes providing a substrate; forming a polysilicon layer over the substrate; oxidizing a portion of the polysilicon layer; and removing the oxidized portion of the polysilicon layer to provide a tapered profile in a vertical direction extending from the substrate for the first and second polysilicon layers.

### BRIEF DESCRIPTION OF THE DRAWINGS

FIG. 1 is a side cross-sectional view of a semiconductor device.

FIG. 2 is a side cross-sectional view of a semiconductor device.

FIG. 3 is a side cross-sectional view of a semiconductor device.

FIG. 4 is a side cross-sectional view of a semiconductor device.

FIG. 5 is a side cross-sectional view of a semiconductor device.

FIG. 6 is a side cross-sectional view of a semiconductor device.

FIG. 7 is a side cross-sectional view of a semiconductor device.

FIG. 8 is a side cross-sectional view of a semiconductor device.

FIG. 9 is a side cross-sectional view of a semiconductor device.

FIG. 10 is a side cross-sectional view of a semiconductor device.

FIG. 11 is a side cross-sectional view of a semiconductor device.

FIG. 12 are side cross-sectional views of oxidation profiles.

### DETAILED DESCRIPTION

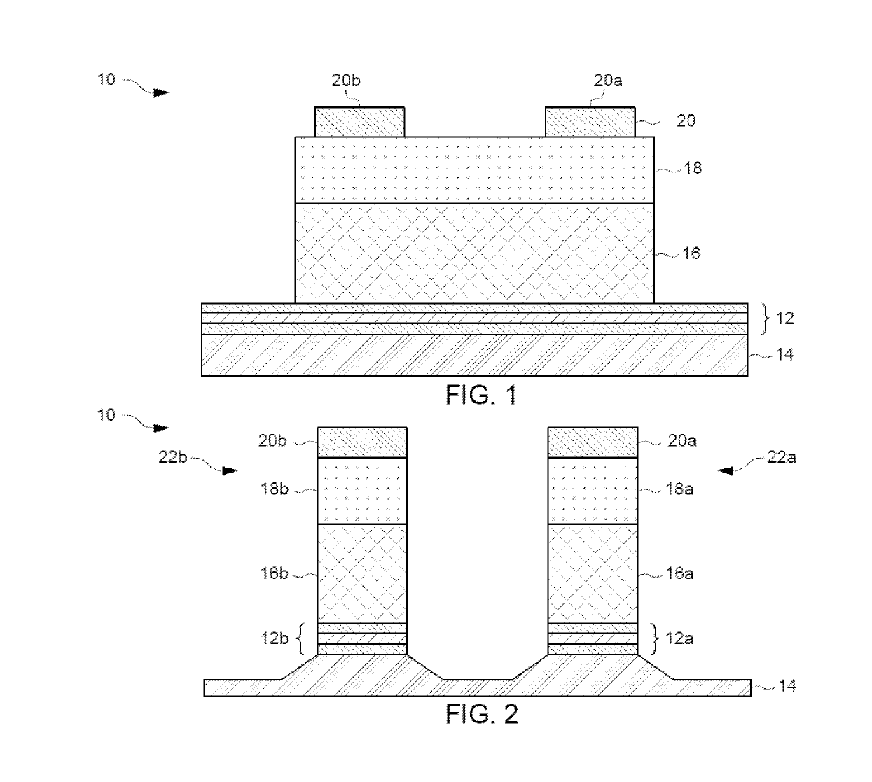

Referring to FIG. 1, the semiconductor device 10 includes a dielectric layer 12 that is formed over a silicon substrate 14. In this embodiment, the dielectric layer 12 is an oxide-nitride-oxide (ONO) layer. A first polysilicon layer 16 is formed over the dielectric layer 12 and a second polysilicon layer 18 is formed over the first polysilicon layer 16. A patterned hard mask layer 20 having a first portion 20a and a second portion 20b is formed over the second polysilicon layer 18.

Referring to FIG. 2, an etching process is performed using the hard mask layer 20 as a mask to create the first structure 22a and the second structure 22b. The etching process may be an anisotropic dry etch. The structures 22a and 22b include the dielectric layer portions 12a and 12b, the first polysilicon layer portions 16a and 16b, the second polysilicon layer portions 18a and 18b and the hard mask layer portions 20a and 20b respectively.

The illustrated structures 22a and 22b are exemplary in nature and the following discussion is applicable to any type of semiconductor structure. For example, the first and second polysilicon layers 16 and 18 may be formed of a single polysilicon layer, and the dielectric layer 12 may be provided as an ONONO periodically laminated layer or an oxide layer. The structures 22a and 22b may be provided for a number of purposes including storage and word line structures for memory devices.

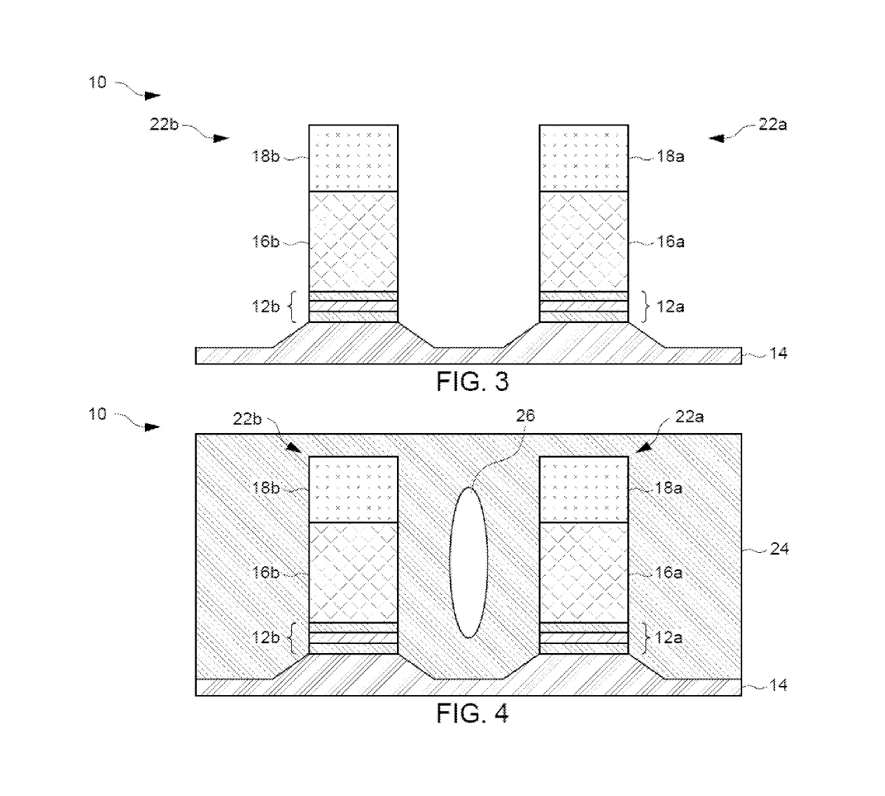

Referring to FIG. 3, the hard mask layer 20 is removed from the semiconductor device 10 shown in FIG. 2.

Referring to FIG. 4, an oxide layer 24 is formed, for example by deposition. A void 26 in the oxide layer 24 is formed between the structures 22a and 22b. The reduction of size and increasing aspect ratios of semiconductor devices contributes to the formation of the void 26.

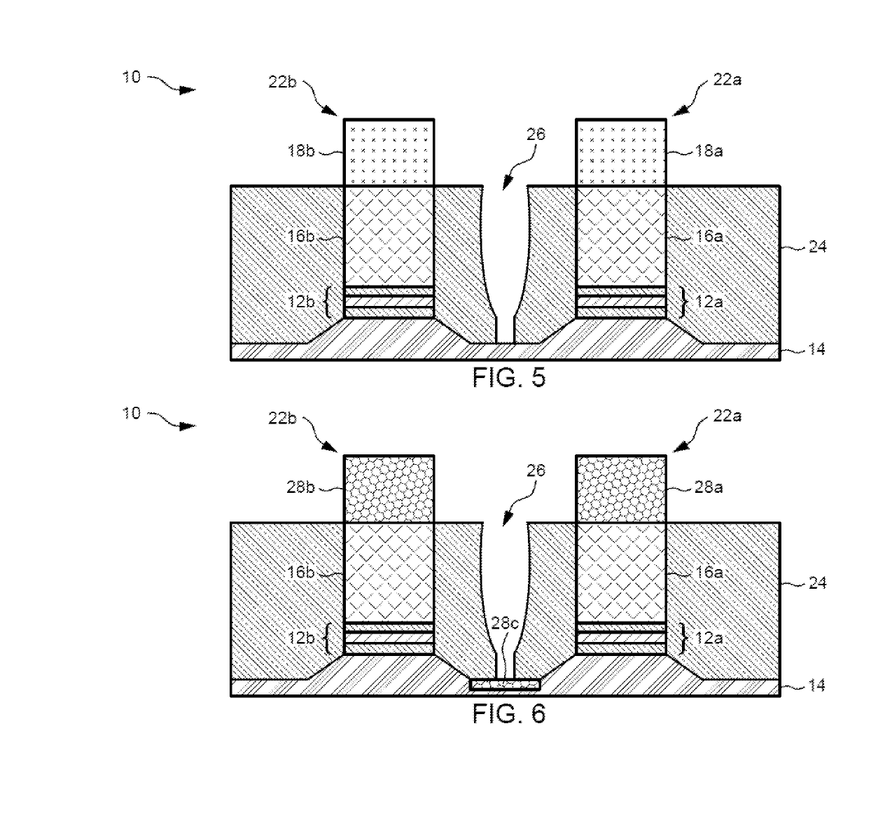

Referring to FIG. 5, a CoSi pre-oxide clean is performed. The cleaning step reduces the oxide layer 24. The cleaning step also exposes the void 26. The exposure of the void 26 during the cleaning step may also lead to an increased size of the void 26. The exposure and/or enlargement of the void 26 exposes the silicon substrate 14.

Referring to FIG. 6, a Co deposition is performed to form CoSi (co-silicide) 28a and 28b on the structures 22a and 22b respectively. The void 26 exposed the silicon substrate 14. Thus, when the Co deposition is performed, CoSi 28c is formed between the structures 22a and 22b. CoSi 28c may act as a bridge between the structures 22a and 22b causing an undesirable short between the structures 22a and 22b. For example, in the case where the structures 22a and 22b are provided in a memory device, a word line short may be formed. Although a Co deposition is described, it will be appreciated that this is merely exemplary in nature and this discussion is applicable to any type of metal silicide or conductive deposition.

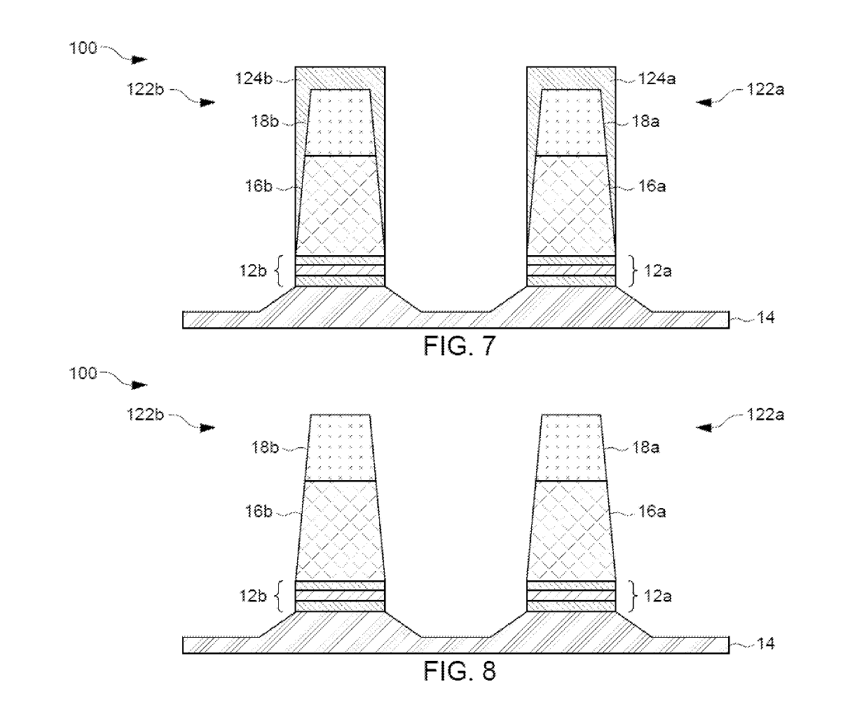

Referring now to FIG. 7, a plasma oxidation is performed on the semiconductor device 10 of FIG. 3 to provide the semiconductor device 100. The semiconductor device 100 includes the silicon substrate 14. The structures 122a and 122b are formed on the silicon substrate 14. The structures 122a and 122b include the dielectric layer portions 12a and 12b, the first polysilicon layer portions 16a and 16b, and the second polysilicon layer portions 18a and 18b respectively. The plasma oxidation forms the oxidation 124a and 124b in the structures 122a and 122b respectively. The oxidation 124a and 124b has a tapered profile.

It will be appreciated that the plasma oxidation step can be performed in a number of ways. For example, with a microwave source, the plasma oxidation may be performed at a temperature of 400-550 C, at a pressure of <1 torr, with a microwave power of 1 kW˜5 kW, and with a gas flow of (O₂+H₂)/(Total Flow) of 0.5˜30%. As another example, with a RF source, the plasma oxidation may be performed at a temperature of 400-550 C, at a pressure of <1 torr, with a RF power of 2 kW˜5 kW, and with a gas flow of (O₂+H₂)/(Total Flow) of 0.5˜30%.

Referring to FIG. 8, the oxide 124a and 124b is removed leaving the structures 122a and 122b having a tapered profile. That is, a top critical dimension (CD) of the structures 122a and 122b is smaller than a bottom dimension of the structures 122a and 122b.

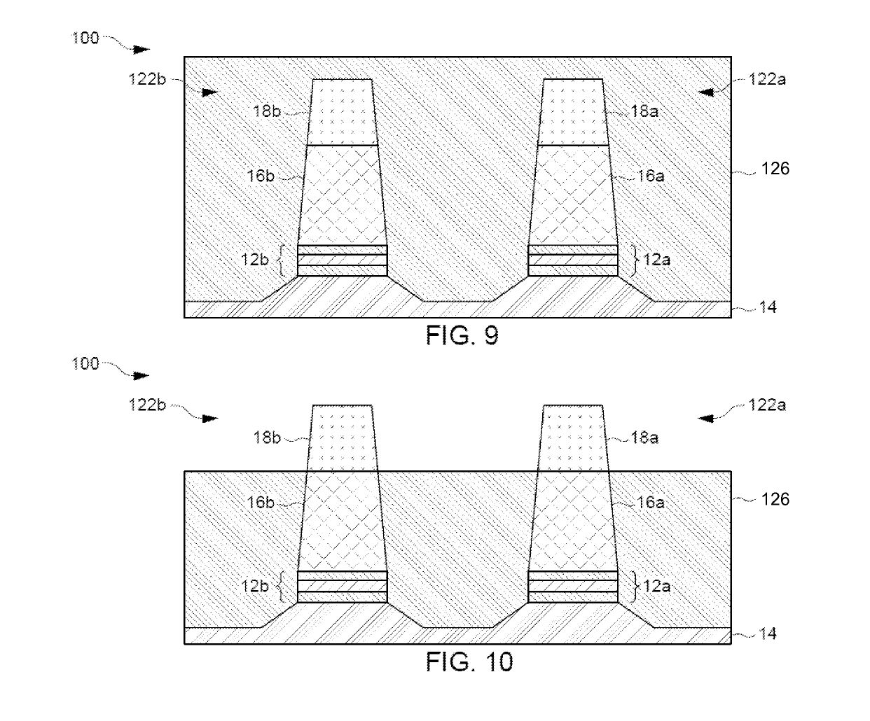

Referring to FIG. 9, an oxide layer 126 is formed, for example by deposition. As compared to the device shown in FIG. 4, the risk of forming a void between the structures 122a and 122b is greatly reduced or eliminated. The tapered profile of the structures 122a and 122b provides for improved oxide fill in performance.

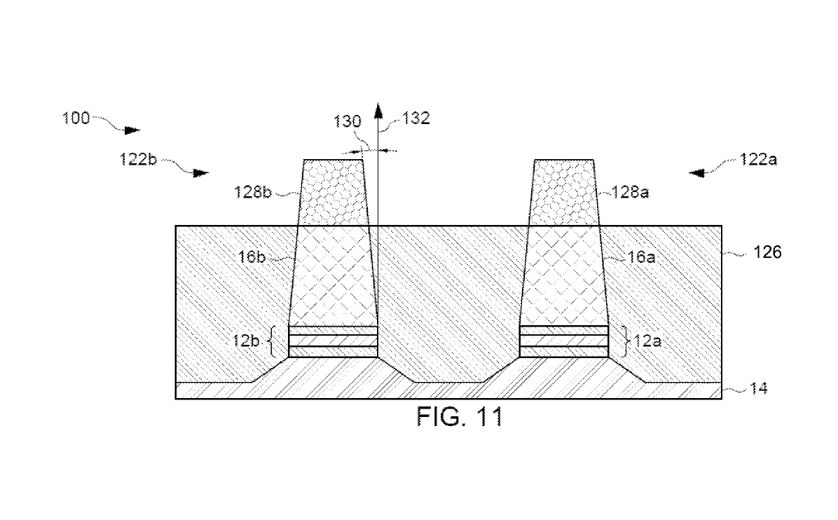

Referring to FIG. 10, a CoSi pre-oxide clean is performed. The cleaning step reduces the oxide layer 126.

Referring to FIG. 11, a Co deposition is performed to form CoSi (co-silicide) 128a and 128b on the structures 122a and 122b respectively. As compared to the device of FIG. 6, the formation of a bridge or short between the structures 122a and 122b has been suppressed. For example, in the case where the structures 122a and 122b are provided in a memory device, the problem of the word line short has been reduced or eliminated.

A sidewall of the structure 122a includes a face of the first polysilicon layer portion 16a and a face of the CoSi 128a that are coplanar. With the tapered profile of the structure 122a, the coplanar portion of the first polysilicon layer 16a and the CoSi 128a forms a non-zero angle 130 with a normal vector 132 of the silicon substrate 14.

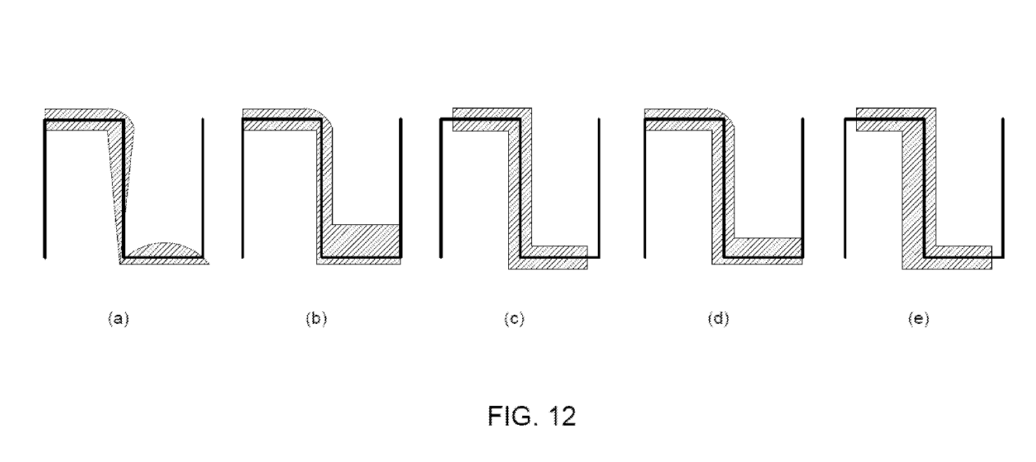

Referring to FIGS. 12, the plasma oxidation profile, for example that described with reference to FIG. 7, can be controlled based on the applied pressure and bias during the plasma oxidation step. FIG. 12A shows a tapered oxidation profile formed with a low pressure and no bias during the plasma oxidation. FIG. 12B shows an oxidation profile with a thicker bottom portion formed with a low pressure and an applied bias during the plasma oxidation. FIG. 12C shows an oxidation profile with sharp corners formed with a high pressure and no bias during the plasma oxidation. FIG. 12D shows an oxidation profile with smoothed corners formed with a high pressure and an applied bias during the plasma oxidation. FIG. 12E shows a reference thermal oxidation profile. In other words, the low pressure and no bias plasma oxidation can oxidate the polysilicon layer anistropically. The top portion of the polysilicon layer converts to oxide material significantly and the bottom portion of the polysilicon layer converts to oxide material slightly. Therefore, the polysilicon layer can be trimmed to a tapered profile after the low pressure and no bias plasma oxidation is performed.

While various embodiments in accordance with the disclosed principles have been described above, it should be understood that they have been presented by way of example only, and are not limiting. Thus, the breadth and scope of the invention(s) should not be limited by any of the above-described exemplary embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantages.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically and by way of example, a description of a technology in the “Background” is not to be construed as an admission that technology is prior art to any invention(s) in this disclosure. Neither is the “Summary” to be considered as a characterization of the invention(s) set forth in issued claims. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings set forth herein.

What is claimed is:

1. A semiconductor device, comprising:
a substrate;
a semiconductor layer formed over the substrate; and
a material layer formed over the semiconductor layer, wherein
the semiconductor layer and the material layer have a tapered profile in a vertical direction extending from the substrate, and
a face of the semiconductor layer and a face of the material layer are coplanar.

2. The semiconductor device of claim 1, wherein the semiconductor layer is a polysilicon layer.

3. The semiconductor device of claim 1, wherein the material layer is a semiconductor layer.

4. The semiconductor device of claim 1, wherein the material layer is a metal silicide layer.

5. The semiconductor device of claim 1, wherein the coplanar faces of the semiconductor layer and the material layer form a non-zero angle with a normal vector of the substrate.

6. The semiconductor device of claim 1, wherein a top dimension of the material layer is smaller than a bottom dimension of the semiconductor layer.

7. The semiconductor device of claim 1, further comprising a dielectric layer between the substrate and the semiconductor layer.

8. The semiconductor device of claim 7, wherein the dielectric layer is a silicon oxide layer.

9. The semiconductor device of claim 7, wherein the dielectric layer is a laminated layer.

10. The semiconductor device of claim 9, wherein the laminated layer is an oxide/nitride/oxide(ONO) layer.

11. The semiconductor device of claim 9, wherein the laminated layer is an oxide/nitride/oxide/nitride/oxide (ONONO) layer.

12. A method of forming a semiconductor device, comprising:
providing a substrate;
forming a polysilicon layer over the substrate;
oxidizing a portion of the polysilicon layer; and
removing the oxidized portion of the polysilicon layer to provide a tapered profile in a vertical direction extending from the substrate for the first and second polysilicon layers.

13. The method of claim 12, wherein the forming a polysilicon layer over the substrate comprises:
forming a first polysilicon layer over the substrate; and
forming a second polysilicon layer over the first polysilicon layer.

14. The method of claim 12, wherein a sidewall of the polysilicon layer forms a non-zero angle with a normal vector of the substrate.

15. The method of claim 12, further comprising converting a top region of the polysilicon layer to a metal silicide layer.

16. The method of claim 15, wherein a face of the remaining polysilicon layer and a face of the metal silicide are coplanar.

17. The method of claim 15, wherein the coplanar faces of the polysilicon layer and the metal silicide form a non-zero angle with a normal vector of the substrate.

18. The method of claim 15, wherein a top dimension of the metal silicide is smaller than a bottom dimension of the first polysilicon layer.

19. The method of claim 12, further comprising forming a dielectric layer over the substrate, wherein the first polysilicon layer is formed over the dielectric layer.

20. The method of claim 19, wherein the dielectric layer is an oxide layer or an oxide/nitride periodically laminated layer.

21. The method of claim 12, wherein the oxidizing the portion of the polysilicon layer and is a plasma oxidation.

22. The method of claim 21, wherein the plasma oxidation is performed under a low pressure condition.

23. The method of claim 12, further comprising forming an oxide layer after the oxidized portion of the polysilicon layer is removed.
